(19) United States
(12) Patent Application Publication
(10) Pub. No.: US 2007/0000443 A1
(43) Pub. Date: Jan. 4, 2007

(54) Vacuum vapor deposition apparatus

(75) Inventor: Shih-Che Chien, Fullerton, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/448,180

(22) Filed: Jun. 7, 2006

(30) Foreign Application Priority Data
Jul. 1, 2005 (CN) 200510035747.1

(51) Int. Cl. C23C 16/00

(52) U.S. Cl. 118/720; 118/726

(57) ABSTRACT

A vacuum vapor deposition apparatus (100) for depositing materials on workpieces includes a vacuum chamber (10), a holding mechanism (20), at least two source material containing devices (30, 40), and at least two adjusting masks (50, 60). The holding mechanism is configured for holding the workpieces, and the holding mechanism is disposed in the vacuum chamber. The source material containing devices are disposed opposite to the holding mechanism in the vacuum chamber. The adjusting masks is rotatably disposed between the holding mechanism and the source material containing devices in the vacuum chamber.

### TECHNICAL FIELD

The present invention generally relates to deposition apparatuses and, more particularly, to a vacuum vapor deposition apparatus.

### BACKGROUND

Optical film is typically used in optical apparatuses, such as cameras, spectacles, interferometers, and semiconductor lasers. The optical film is deposited on an optical element in a vacuum vapor deposition apparatus. A typical vacuum vapor deposition apparatus includes a vacuum chamber, at least one target source, and a rotatable support means for holding optical substrates. The target source and the rotatable support means are both disposed in the vacuum chamber.

In a typical vacuum deposition apparatus, an umbrella-like support means is used for holding optical substrates. When using the umbrella-like support means, the optical substrates held in a central area of the support means will be coated with different thicknesses of film. Thus an adjusting mask is disposed between the umbrella-like support means and the target source for adjusting the thickness of the film. However, the adjusting mask can only control the thickness of one film at a time. When an optical substrate needs to be coated with more than one film, the adjusting mask cannot properly adjust the thickness of the films and the surface may be coated unevenly.

Therefore, a vacuum vapor deposition apparatus which can overcome the above-described problem is desired.

### SUMMARY

In one embodiment thereof, a vacuum vapor deposition apparatus for depositing materials on workpieces includes a vacuum chamber, a holding mechanism, at least two source material containing devices, and at least two adjusting masks. The holding mechanism is configured for holding the workpieces, and the holding mechanism is disposed in the vacuum chamber. The source material containing devices are disposed opposite to the holding mechanism in the vacuum chamber. The adjusting masks is rotatably disposed between the holding mechanism and the source material containing devices in the vacuum chamber.

Other advantages and novel features will become more apparent from the following detailed description when taken in conjunction with the accompanying drawings.

### BRIEF DESCRIPTION OF THE DRAWING

Many aspects of the vacuum vapor deposition apparatus can be better understood with reference to the following drawing. The components in the drawing are not necessarily drawn to scale, the emphasis instead being placed upon clearly illustrating the principles of the present vacuum vapor deposition apparatus. Moreover, in the drawing, like reference numerals designate corresponding parts throughout.

FIG. 1 is a schematic view of a vacuum vapor deposition apparatus in accordance with a preferred embodiment.

### DETAILED DESCRIPTION OF THE EMBODIMENT

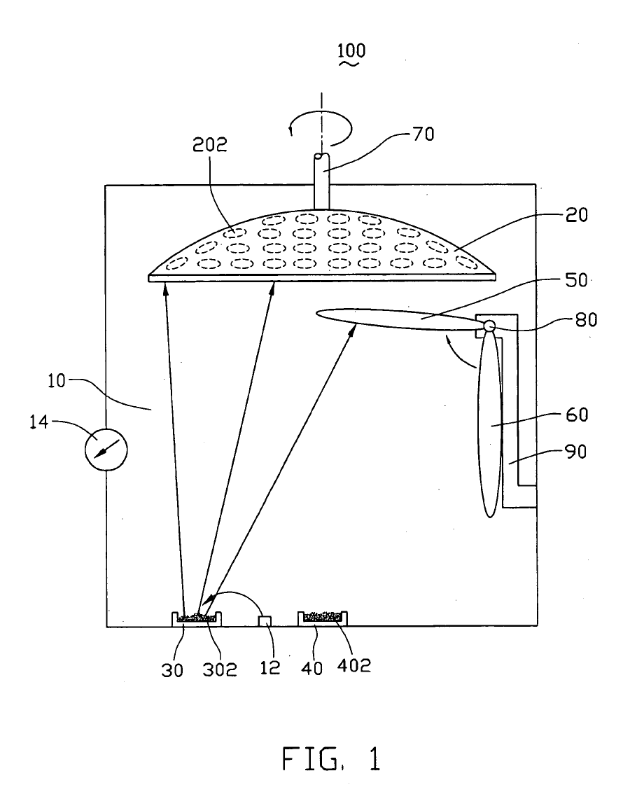

Referring to FIG. 1, in a preferred embodiment, a vacuum vapor deposition apparatus 100 includes a vacuum chamber 10, a holding mechanism 20, a first source material containing device 30, a second source material containing device 40, a first adjusting mask 50, and a second adjusting mask 60.

The vacuum chamber 10 contains the holding mechanism 20, the first source material containing device 30, the second source material containing device 40, the first adjusting mask 50, and the second adjusting mask 60. The holding mechanism 20 has an umbrella-like shape, and is detachably installed in one side of the vacuum chamber 10. In this embodiment, the holding mechanism 20 is installed in an upper portion inside the vacuum chamber 10. The holding mechanism 20 has a predetermined number of holding positions 202 for holding workpieces. The holding mechanism 20 is connected to a driving device 70 for driving the holding mechanism 20 to rotate.

The first source material containing device 30 and the second source material containing device 40 are disposed on an opposite side to the holding mechanism 20 in the vacuum chamber 10. In this embodiment, the first source material containing device 30 and the second source material containing device 40 are both disposed on a lower portion inside the vacuum chamber 10. A first source material 302 is contained in the first source material containing device 30, and a second source material 402 is contained in the second source material containing device 40.

The first adjusting mask 50 and the second adjusting mask 60 are both installed on a supporting frame 90 with a rotatable mechanism 80 in the vacuum chamber 10. In this embodiment, the rotatable mechanism 80 is a hinge. The first adjusting mask 50 and the second adjusting mask 60 have different shapes or areas designed according to the source materials 302, 402. In this embodiment, the adjusting masks 50, 60 are circular in shape.

In the vacuum chamber 10, an electron gun 12 is disposed near the source material containing device 30, 40 for evaporating the source materials 302, 402. A pressure sensor 14 is connected to the vacuum chamber 10 for detecting pressure in the vacuum chamber 10.

During operation of the vacuum vapor deposition apparatus 100, firstly, a plurality of workpieces are positioned on the holding positions 202 of the holding mechanism 20. Secondly, the holding mechanism 20 is installed in the vacuum chamber 10 in a manner so as to be connected to the driving device 70. Thirdly, the vacuum chamber 10 is sealed, and is evacuated to a predetermined pressure. Fourthly, the driving device 70 drives the holding mechanism 20 to rotate at a predetermined speed. Fifthly, the first adjusting mask 50 is rotated to a position covering a portion of the holding mechanism 20 by means of a rotatable mechanism 80. Sixthly, the first source material 302 is evaporated by the electron gun 12, and a first film is deposited on the workpieces. Seventhly, the first adjusting mask 50 is rotated to an initial position, and the second adjusting mask 60 is rotated to the position covering a portion of the holding mechanism 20. Eighthly, the second source material 402 is evaporated by the electron gun 12, and a second film is deposited on the surface of the first film. Finally, the driving device is stopped, and the workpieces are taken out of the vacuum chamber 10 after the vacuum chamber 10 is opened. In the seventh step, if the second adjust mask 60 has a larger area than the first adjusting mask 50, the first adjusting mask 50 may not be rotated to the initial position.

Understandably, the vacuum vapor deposition apparatus 100 can have more than two adjusting masks if the source materials are more than two types. The first adjusting mask 50 and the second adjusting mask 60 can be installed on different supporting frames in the vacuum chamber 10. Each of the adjusting masks is designed to suit one type of material resource. Thus, the vacuum vapor deposition apparatus 100 is capable of depositing films evenly.

It is believed that the present embodiments and their advantages will be understood from the foregoing description, and it will be apparent that various changes may be made thereto without departing from the spirit and scope of the invention or sacrificing all of its material advantages, the examples here before described merely being preferred or exemplary embodiments of the invention.

What is claimed is:

1. A vacuum vapor deposition apparatus for depositing materials on workpieces, comprising:
a vacuum chamber;
a holding mechanism configured for holding the workpieces, the holding mechanism being disposed in the vacuum chamber;
at least two source material containing devices disposed opposite the holding mechanism in the vacuum chamber and configured for containing source materials; and
at least two adjusting masks rotatably disposed between the holding mechanism and the source material containing devices in the vacuum chamber.

2. The apparatus as claimed in claim 1, wherein the source material containing devices are crucibles.

3. The apparatus as claimed in claim 2, wherein each of the adjusting masks is provided for each of the crucibles.

4. The apparatus as claimed in claim 1, further comprising a supporting frame in the vacuum chamber, the adjusting masks are installed on the supporting frame.

5. The apparatus as claimed in claim 4, wherein the supporting frame has hinges connecting the adjusting masks.

6. The apparatus as claimed in claim 1, wherein the holding mechanism has an umbrella-like shape.

7. The apparatus as claimed in claim 1, wherein the holding mechanism connects a driving device for driving the rotation of the holding mechanism.

8. The apparatus as claimed in claim 1, wherein the holding mechanism has a plurality of holding positions for holding a plurality of workpieces.

9. The apparatus as claimed in claim 1, wherein an electron gun is disposed in the apparatus for evaporating the source materials.

10. The apparatus as claimed in claim 1, wherein a pressure sensor is connected to the vacuum chamber for detecting the pressure in the vacuum chamber.

11. A vacuum vapor deposition apparatus comprising:
a vacuum chamber;
a holding mechanism located in an upper portion inside the vacuum chamber, the holding mechanism being configured for holding workpieces;
a plurality of source material containing devices including a first source material containing device and a second source material containing device, the first and second source material containing devices located in a lower portion inside the vacuum chamber and configured for containing first and second deposition materials, respectively; and
an adjusting mask assembly located inside the vacuum chamber and including a first adjusting mask and a second adjusting mask, the first and second adjusting masks each being configured so as to cover a portion of the holding mechanism.

12. The apparatus as claimed in claim 11, wherein the source material containing devices are crucibles.

13. The apparatus as claimed in claim 11, further comprising a supporting frame in the vacuum chamber, the adjusting mask assembly is installed on the supporting frame.

14. The apparatus as claimed in claim 11, wherein the holding mechanism connects a driving device for driving the rotation of the holding mechanism.

15. The apparatus as claimed in claim 11, wherein an electron gun is disposed near to source material containing devices for evaporating the first and second deposition materials.

16. The apparatus as claimed in claim 11, wherein the first and second adjusting masks is installed in a side portion inside the vacuum chamber, and the first and second adjusting mask are each movable between said side portion and a covering position where the portion of the holding mechanism is covered.

17. The apparatus as claimed in claim 11, wherein the first and second adjusting masks can selectively cover the holding portions.

18. The apparatus as claimed in claim 11, wherein the first and second adjusting masks have distinct area so as to cover different portions of the holding mechanism.
